(19) United States
(12) Patent Application Publication
(10) Pub. No.: US 2008/0001289 A1
(43) Pub. Date: Jan. 3, 2008

(54) STACKED-TYPE WAFER LEVEL PACKAGE, METHOD OF MANUFACTURING THE SAME, WAFER-LEVEL STACK PACKAGE AND METHOD OF MANUFACTURING THE SAME

(75) Inventor: Keum-Hee MA, Gyeongsangbuk-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/770,602

(22) Filed: Jun. 28, 2007

(30) Foreign Application Priority Data
Jun. 28, 2006 (KR) 2006-58780

(51) Int. Cl. H01L 23/48; H01L 21/44; H01L 21/60

(52) U.S. Cl. 257/737; 438/107; 438/613; 257/E23.01; 257/E21.476; 257/E21.506

(57) ABSTRACT

A stacked-type wafer level package includes a semiconductor chip through which a hole is formed, a conductive pattern and a conductive bump. The conductive pattern includes a conductive trace formed on an upper face of the semiconductor chip and electrically connected to the semiconductor chip, and a conductive pad extending from the conductive trace through the hole. The conductive pad is not protruded from a lower face of the semiconductor chip. The conductive bump is positioned on the conductive trace over the conductive pad.

### CROSS-REFERENCE TO RELATED APPLICATION

This application claims priority under 35 USC §119 to Korean Patent Application No. 2006-58780 filed on Jun. 28, 2006, the contents of which are herein incorporated by reference in their entirety.

### BACKGROUND

1. Field of the Invention

Example embodiments of the present invention relate to a stacked-type wafer level package, a method of manufacturing the same, a wafer-level stack package, and method of manufacturing the same. More particularly, example embodiments of the present invention relate to a stacked-type wafer level package having a conductive pad that does not protrude from the bottom of a semiconductor chip, a method of manufacturing the stacked-type wafer level package, a wafer-level stack package in which the wafer-level packages are sequentially stacked, and a method of manufacturing the wafer-level stack package.

2. Description of the Related Art

Over the years, the overall size and weight of electronic devices has been greatly reduced as technologies to manufacture semiconductor devices have been developed. Accordingly, semiconductor packages that are used as important parts of the electronic devices have also been reduced in size and weight. An example of the semiconductor packages developed in accordance with this trend includes a chip stack package that includes a substrate and a plurality of semiconductor chips vertically stacked on the substrate.

It is more advantageous to use the chip stack package rather than a plurality of unit semiconductor packages when manufacturing a semiconductor device, since the chip stack package has a smaller size, a lighter weight and a smaller mounting area than those of the plurality of unit semiconductor packages, thereby enabling the semiconductor device to be reduced in size and weight. In past years, the chip stack package mainly included a chip-level stack package. However, the chip stack package currently includes a wafer-level stack package.

FIG. 1 is a cross-sectional view illustrating a conventional wafer-level stack package.

Referring to FIG. 1, a conventional wafer-level stack package 100 includes a first package 10 and a second package 50 stacked on the first package 10.

The first package 10 includes a first semiconductor chip 11, a first insulation layer 30, a first seed layer 20, a first conductive pad 42 and a first conductive trace 44. The second package 50 includes a second semiconductor chip 61, a second insulation layer 70, a second seed layer 80, a second conductive pad 92 and a second conductive trace 94. Here, the first package 10 and the second package 50 have structures substantially the same as each other. Thus, only the first package 10 is described below.

A bonding pad 12 is formed on an upper face of the first semiconductor chip 11. A hole 13 is vertically formed through the first semiconductor chip 11. The first insulation layer 30 is formed on the upper face of the semiconductor chip 11 and an inner wall of the hole 13 to expose the bonding pad 12. The first seed layer 20 is formed on the first insulation layer 30. The first conductive pad 42 is formed on the first seed layer 20 by a plating process to fill up the hole 13 with the first conductive pad 42. Here, a lower end of the first conductive pad 42 is protruded from a lower face of the first semiconductor chip 11. The first conductive trace 44 is formed on the first seed layer 20 over the first semiconductor chip 11. The first conductive trace 44 is electrically connected to the bonding pad 12 and the first conductive pad 42.

When the second package 50 is stacked on the first package 10, a lower end of the second conductive pad 92, which is protruded through a hole 63, in the second package 50 electrically makes contact with the first conductive trace 44 of the first package 10.

FIGS. 2A to 2C are cross-sectional views illustrating a conventional method of manufacturing the wafer-level stack package in FIG. 1.

Referring to FIG. 2A, the lower face of the first semiconductor chip 11 is subjected to a grinding process to expose the lower end of the first conductive pad 42.

Referring to FIG. 2B, the ground lower face of the first semiconductor chip 11 is removed by a spin wet etching process using an etchant for silicon until the lower end of the first conductive pad 42, the first insulation layer 30 and the first seed layer 20 are protruded from the lower face of the first semiconductor chip 11.

Referring to FIG. 2C, the first insulation layer 30 surrounding the lower end of the first conductive pad 42 is removed by a spin wet etching process using an etchant for an insulation material to expose the lower end of the first conductive pad 42 from the lower face of the first semiconductor chip 11.

The conventional method of manufacturing the wafer-level stack package requires performing the grinding process and the two wet etching processes on the lower face of the semiconductor chip to protrude the conductive pad from the semiconductor chip, thereby adding more processes to manufacture the wafer-level stack package.

Further, a wafer including a plurality of semiconductor chips may be warped or broken when the above-mentioned processes are carried out. This is especially true when the grinding and etching processes substantially reduce the thickness of the semiconductor chips. For instance, the final thickness of the semiconductor chips may be about 50 μm, in which case, the semiconductor chips are highly susceptible to warpage and breaking during processing steps.

Also, when the conductive pad is bonded to the conductive trace, the first conductive trace of the first package may make contact with a lower face of the second semiconductor chip in the second package to form a current path through the first conductive trace and the second semiconductor chip. Therefore, a leakage current may flow through the current path so that the conventional wafer-level stack package may have poor reliability.

The invention addresses these and other disadvantages of the conventional method.

### SUMMARY

Example embodiments of the present invention provide a stacked-type wafer level package that is manufactured by simple processes and has good electrical reliability. Other example embodiments of the present invention provide a wafer-level stack package in which the above-mentioned wafer level packages are stacked. Example embodiments of the present invention further provide a method of manufacturing the above-mentioned stacked-type wafer level package. Example embodiments of the present invention also provide a method of manufacturing the above-mentioned wafer-level stack package.

### BRIEF DESCRIPTION OF THE DRAWINGS

The above and other features and advantages of the invention will become readily apparent by reference to the following detailed description when considered in conjunction with the accompanying drawings wherein:

FIG. 1 is a cross-sectional view illustrating a conventional wafer-level stack package;

FIGS. 2A to 2C are cross-sectional views illustrating a conventional method of manufacturing the wafer-level stack package in FIG. 1;

FIG. 3 is a cross-sectional view illustrating a stacked-type wafer level package in accordance with a first example embodiment of the present invention;

FIGS. 4A to 41 are cross-sectional views illustrating a method of manufacturing the stacked-type wafer level package of FIG. 3;

FIG. 5 is a cross-sectional view illustrating a stacked-type wafer level package in accordance with a second example embodiment of the present invention;

FIG. 6 is a cross-sectional view illustrating a wafer-level stack package in accordance with a third example embodiment of the present invention; and

FIG. 7 is a cross-sectional view illustrating a wafer-level stack package in accordance with a fourth example embodiment of the present invention.

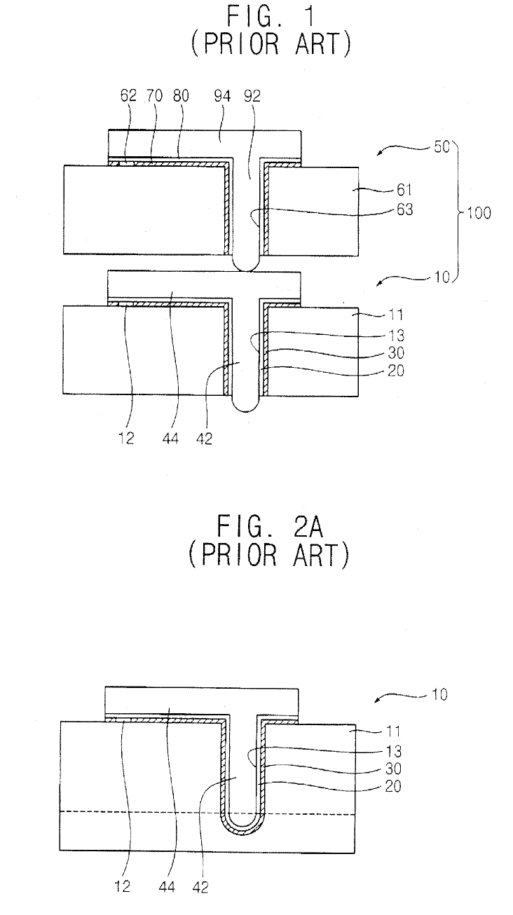

### DETAILED DESCRIPTION OF PREFERRED EMBODIMENTS

The present invention is described more fully hereinafter with reference to the accompanying drawings, in which embodiments of the invention are shown. The invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Embodiment 1

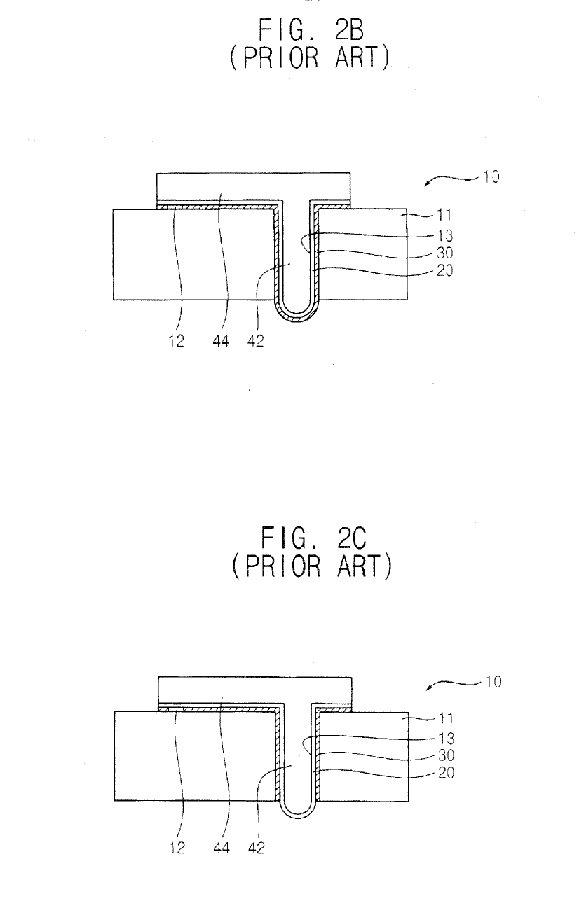

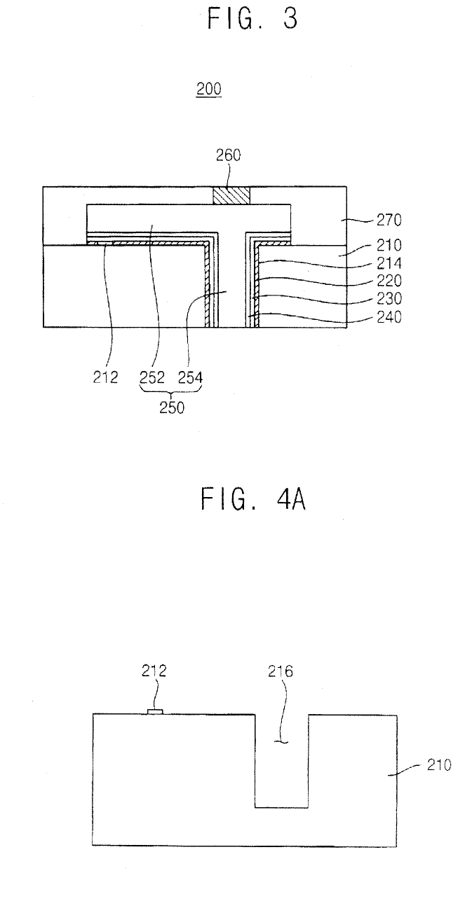

FIG. 3 is a cross-sectional view illustrating a stacked-type wafer level package in accordance with a first example embodiment of the present invention.

Referring to FIG. 3, a stacked-type wafer level package 200 of this example embodiment includes a semiconductor chip 210, a first insulation layer 220, a barrier layer 230, a seed layer 240, a conductive pattern 250, a conductive bump 260 and a second insulation layer 270.

The semiconductor chip 210 includes a bonding pad 212 that is configured to be electrically connected to an external device. A hole 214 is vertically formed through the semiconductor chip 210.

The first insulation layer 220 is formed on an upper face of the semiconductor chip 210 and an inner wall of the hole 214. Further, the first insulation layer 220 has an opening for exposing the bonding pad 212.

The barrier layer 230 is formed on the first insulation layer 220. The barrier layer 230 improves electrical characteristics of the conductive pattern 250. In this example embodiment, examples of the barrier layer 230 may include a titanium layer, a titanium nitride layer, a titanium tungsten layer, a platinum silicon layer, an aluminum layer, a metal alloy layer thereof, etc.

The seed layer 240 is formed on the barrier layer 230. The seed layer 240 is used for forming the conductive pattern 250 in an electroplating or electroless plating process.

The conductive pattern 250 is formed on the seed layer 240. The conductive pattern 250 includes a conductive trace 252 and a conductive pad 254. The conductive trace 252 is formed on the upper face of the semiconductor chip 210. Further, the conductive trace 252 is electrically connected to the bonding pad 212. The conductive pad 254 extends from the conductive trace 252 through the hole 214 toward a lower face of the semiconductor chip 210. Thus, the hole 214 is fully filled with the conductive pad 254. In this example embodiment, the conductive pad 254 has a lower end positioned on a plane substantially the same as the lower face of the semiconductor chip 210. In other words, the lower end of the conductive pad 254 is substantially level with the lower face of the semiconductor chip 210. Here, the conductive pad 254 may include a material having good dielectric characteristics such as a desired impedance and power consumption rate. Particularly, examples of the material used for the conductive pad 254 may include copper, gold, tungsten, etc. Further, since the conductive trace 252 may be formed simultaneously with the conductive pad 254 using substantially the same material, the conductive trace 252 may include a material substantially the same as that of the conductive pad 254.

The conductive bump 260 is formed on the conductive trace 252. Particularly, the conductive bump 260 is positioned on an upper face of the conductive trace 252 over the conductive pad 254. That is, the conductive bump 260 is placed on a vertical axis of the conductive pad 254. Thus, the conductive bump 260 serves to electrically connect two packages together, as shown in FIG. 6 and described below.

In this example embodiment, the conductive bump 260 has a rectangular cross section. Therefore, the conductive bump 260 has a flat upper face. Here, since a flat lower end of a conductive pad in another package of structure substantially the same as that of the package 200 in FIG. 3 makes contact with the upper face of the conductive bump 260 to electrically connect the two packages to each other, the flat upper face of the conductive bump 260 may ensure a reliable electrical connection between the two packages.

Alternatively, the conductive bump 260 may have a spherical shape. When the conductive bump 260 has the spherical shape, the spherical conductive bump 260 may have a diameter of about 20 μm. In contrast, a solder ball for an outer terminal of a semiconductor package may have a diameter of about 100 μm.

The second insulation layer 270 is formed on the semiconductor chip 210 and the conductive trace 252. Here, since the conductive bump 260 is electrically connected to the lower end of the conductive pad in another package, the second insulation layer 270 has an opening for exposing the conductive bump 260. In this example embodiment, the second insulation layer 270 has an upper face that is placed on a plane substantially the same as that of the conductive bump 260. In other words, the top surface of the conductive bump 260 may be substantially level with the top surface of the second insulation layer. However, when the conductive bump 260 has a spherical shape, the conductive bump 260 may protrude above the top surface of the second insulation layer 270. Further, an example of the second insulation layer 270 may include a polymer.

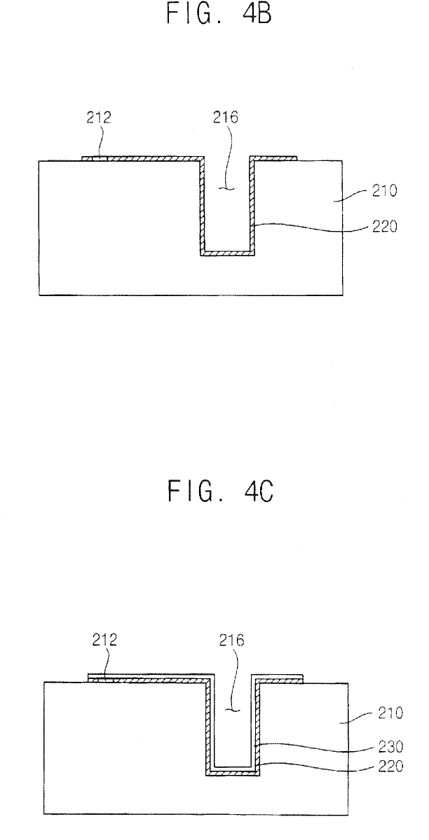

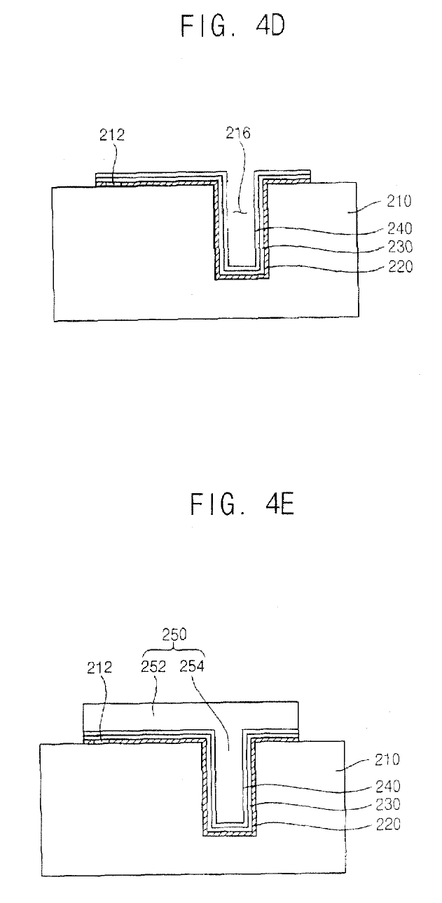

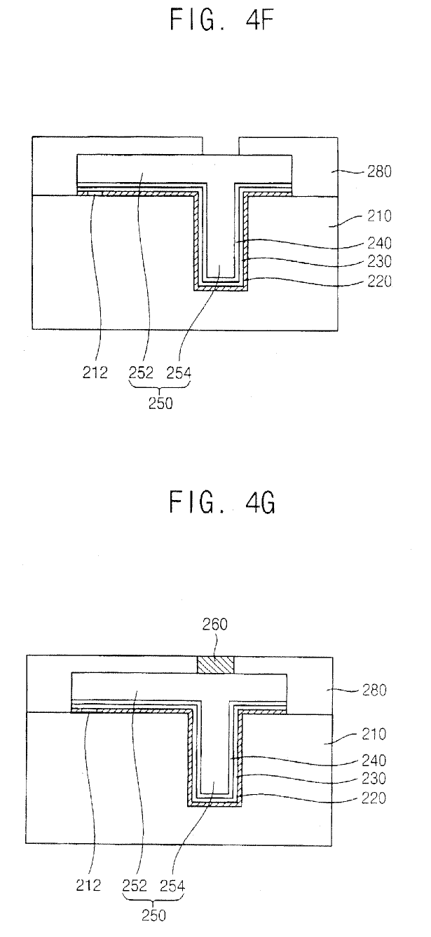

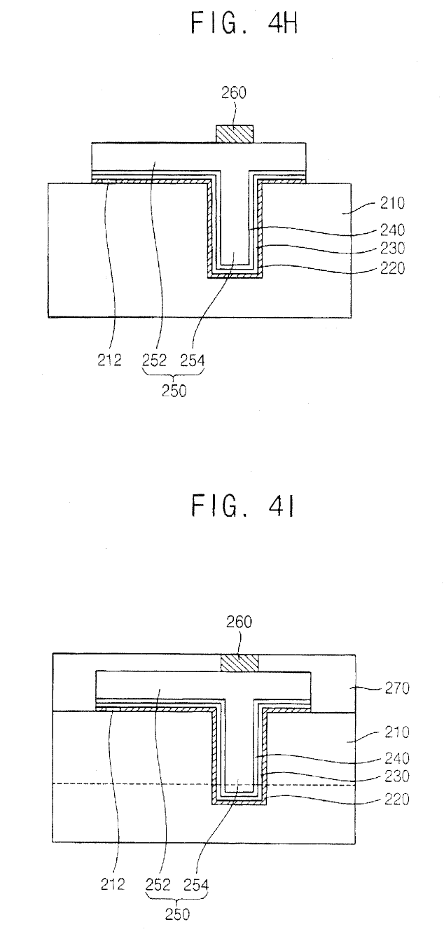

FIGS. 4A to 4I are cross-sectional views illustrating a method of manufacturing the stacked-type wafer level package of FIG. 3.

Referring to FIG. 4A, a preliminary hole 216 is formed from the upper face of the semiconductor chip 210 having the bonding pad 212 using a piercing tool such as a laser drill. Other methods known in the art for forming preliminary hole 216 may also be utilized, such as a large-aspect-ratio etching process. Here, the preliminary hole 216 is not exposed through the lower face of the semiconductor chip 210. That is, the preliminary hole 216 has a depth smaller than the thickness of the semiconductor chip 210.

Referring to FIG. 4B, the first insulation layer 220 is formed on the upper face of the semiconductor chip 210 and in the preliminary hole 216. Here, the first insulation layer 220 has an opening for exposing the bonding pad 212.

Referring to FIG. 4C, the barrier layer 230 is formed on the first insulation layer 220. Examples of the barrier layer 230 may include a titanium layer, a titanium nitride layer, a titanium tungsten layer, a platinum silicon layer, an aluminum layer, a metal alloy layer thereof, etc. Further, the barrier layer 230 may be formed by a sputtering process, an evaporation process, etc.

Referring to FIG. 4D, the seed layer 240 is formed on the barrier layer 230. The seed layer 240 is used for a subsequent electroplating process.

Referring to FIG. 4E, the conductive pattern 250 is formed on the seed layer 240 to fill up the preliminary hole 216 with the conductive pattern 250. Particularly, when the electroplating process or an electroless plating process is carried out on the seed layer 240, a metal layer (not shown) is formed on the seed layer 240. Examples of the metal layer may include copper, gold, tungsten, etc. The metal layer is patterned to form the conductive pattern 250. Here, the conductive pattern 250 includes the conductive trace 252 over the semiconductor chip 210 and the conductive pad 254 in the preliminary hole 216. Further, the conductive trace 252 has a first end electrically connected to the bonding pad 212 and a second end on which a conductive bump is subsequently formed.

Referring to FIG. 4F, a photoresist pattern 280 is formed on the semiconductor chip 210 and the conductive trace 252. Here, the photoresist pattern 280 has an opening to expose an upper face of the conductive trace 252 over the conductive pad 254.

Referring to FIG. 4G, an electroplating process or an electroless plating process is carried out on the upper face of the conductive trace 252 exposed through the opening of the photoresist pattern 280 to form the conductive bump 260 in the opening. Thus, the conductive bump 260 is placed over the conductive pad 254.

Referring to FIG. 4H, the photoresist pattern 280 is then removed by an ashing process and/or a stripping process.

Referring to FIG. 4I, the second insulation layer 270 is formed on the semiconductor chip 210 and the conductive trace 252. The second insulation layer 270 protects the conductive trace 252, the conductive pad 254 and the conductive bump 260 from an external environment. Further, when a conductive pad and a conductive bump in vertically stacked upper and lower packages are bonded to each other, the second insulation layer 270 prevents the conductive trace of the lower package from making contact with a semiconductor chip of the upper package. In this example embodiment, the second insulation layer 270 has an upper face that is positioned on a plane substantially the same as that of the conductive bump 260. In other words, a top surface of the second insulation layer 270 may be substantially level with a top surface of the conductive bump 260.

The lower face of the semiconductor chip 210 is partially removed to expose the lower end of the conductive pad 254. Here, the lower face of the semiconductor chip 210 may be removed by a chemical mechanical polishing (CMP) process, a spin wet etching process, etc. Particularly, when the wet etching process is performed on the lower face of the semiconductor chip 210, a thickness of the semiconductor chip 210 may be reduced to no more than about 50 μm without generating mechanical damage to the semiconductor chip 210.

Alternatively, only the lower face of the semiconductor chip 210 may be removed to expose the lower end of the conductive pad 254 without having the lower end of the conductive pad 254 removed. However, since controlling the process in accordance with the above-mentioned conditions is very difficult, the lower end of the conductive pad 254 as well as the semiconductor chip 210 are partially removed in this example embodiment. As a result, the hole 214 of the semiconductor chip 210 resulting from the removal process has a depth smaller than that of the preliminary hole 216.

Here, the above-mentioned semiconductor chips 210 are formed in a single wafer. Thus, the wafer is sawn along a scribe lane to separate the wafer from the semiconductor chips 210, thereby completing the stacked-type wafer level package 200 in FIG. 3.

### Embodiment 2

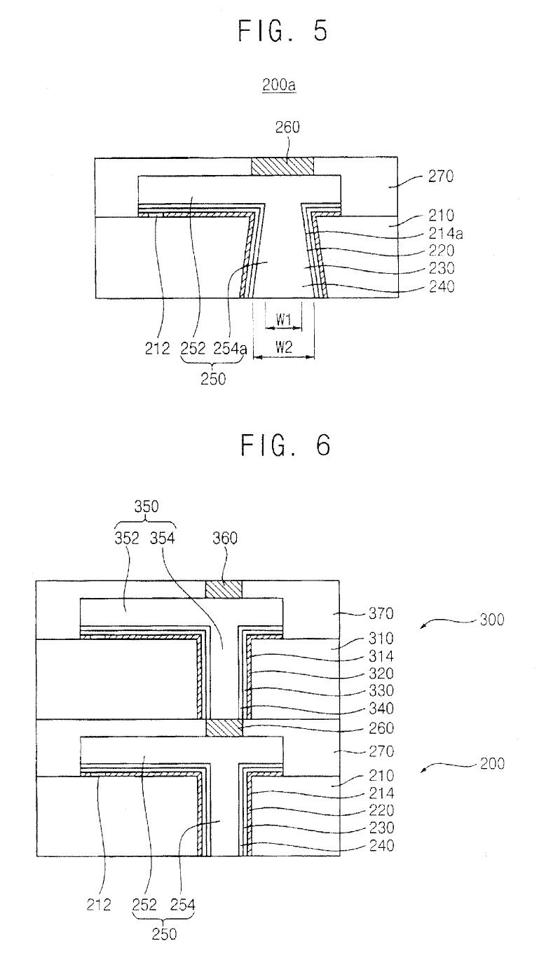

FIG. 5 is a cross-sectional view illustrating a stacked-type wafer level package in accordance with a second example embodiment of the present invention.

The stacked-type wafer level package 200a of this example embodiment includes elements substantially the same as those of the stacked-type wafer level package 200 in Embodiment 1 except for the hole and the conductive pad. Thus, the same reference numerals refer to the same elements, and thus any further illustrations with respect to the same elements are omitted herein for brevity.

Referring to FIG. 5, the hole 214a that is formed through the semiconductor chip 210 has an upper width and a lower width greater than the upper width. In other words, hole 214a has a lower width larger than the upper width. Particularly, the hole 214a has a tapered shape. Therefore, the conductive pad 254a in the hole 214a also has an upper width W1 and a lower width W2 greater than the upper width W1. That is, the conductive pad 254a has an upper area and a lower area larger than the upper area.

When the conductive pad 254a has the lower area larger than the upper area, a contact area between the conductive pad 254a and a conductive bump in another package is enlarged. As a result, electrical contact reliability between the conductive pad 254a and the conductive bump may be improved. Further, the enlarged contact area between the conductive pad 254a and a conductive bump of another package can allow for a small amount of misalignment between the two packages, thereby also resulting in a more reliable semiconductor device.

Here, a method of manufacturing the stacked-type wafer level package in FIG. 5 is substantially the same as that illustrated with reference to FIGS. 3 and 4A to 4I in Embodiment 1 except for a process for forming the hole 214a. That is, when the hole 214a is formed through the semiconductor chip 210, the hole 214a is provided with the lower width larger than the upper width. Herein, any further illustrations with respect to the same processes are omitted for brevity.

### Embodiment 3

FIG. 6 is a cross-sectional view illustrating a wafer-level stack package in accordance with a third example embodiment of the present invention.

Referring to FIG. 6, a wafer-level stack package of this example embodiment includes a first package 200 and a second package 300 stacked on the first package 200.

The first package 200 includes a first semiconductor chip 210, a first insulation layer 220, a first barrier layer 230, a first seed layer 240, a first conductive pattern 250 having a first conductive trace 252 and a first conductive pad 254, a first conductive bump 260 and a second insulation layer 270.

The second package 300 includes a second semiconductor chip 310, a third insulation layer 320, a second barrier layer 330, a second seed layer 340, a second conductive pattern 350 having a second conductive trace 352 and a second conductive pad 354, a second conductive bump 360, and a fourth insulation layer 370. In some cases, the second conductive bump 360 may be omitted, for instance, when no other packages are to be stacked on the second package 300.

Here, the first and second packages 200 and 300 include elements substantially the same as those of the stacked-type wafer level package in FIG. 3. Thus, any further illustrations with respect to the first and second packages 200 and 300 are omitted herein.

The second conductive pad 354 of the second package 300 is bonded to the first conductive bump 260 of the first package 200 to electrically connect the first package 200 to the second package 300.

Here, a method of manufacturing the wafer-level stack package includes processes substantially the same as those in Embodiment 1. The method of manufacturing the wafer-level stack package further includes a process for bonding the second conductive pad 354 of the second package 300 to the first conductive bump 260 of the first package 200, which may include a thermal compression process.

### Embodiment 4

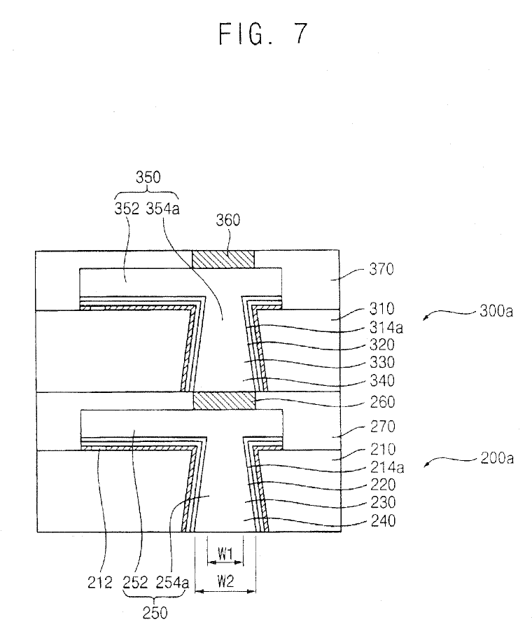

FIG. 7 is a cross-sectional view illustrating a wafer-level stack package in accordance with a fourth example embodiment of the present invention.

The wafer-level stack package of this example embodiment includes elements substantially the same as those of the wafer-level stack package in Embodiment 3 except for the holes and the conductive pads. Thus, reference numerals refer to the same elements and any further illustrations with respect to the same elements are omitted herein for brevity.

Referring to FIG. 7, first and second holes 214a and 314a that are formed through the first and second semiconductor chips 210 and 310, respectively, have an upper width and a lower width greater than the upper width. In other words, first and second holes 214a and 314a have a lower width larger than the upper width. Particularly, the first and second holes 214a and 314a have a tapered shape. Therefore, first and second conductive pads 254a and 354a in the first and second holes 214a and 314a, respectively, also have an upper width W1 and a lower width W2 greater than the upper width, so that the conductive pad 254a has an upper area and a lower area larger than the upper area. That is, the wafer level package of this example embodiment has a structure in which the packages in Embodiment 2 are vertically stacked.

When the first and second conductive pads 254a and 354a have the lower area larger than the upper area, a contact area between the first conductive bump 260 of the first package 200 and the second conductive pad 354a of the second package 300 is enlarged. As a result, electrical contact reliability between the first package 200 and the second package 300 may be improved.

Here, a method of manufacturing the stacked-type wafer level package in FIG. 7 is substantially the same as that in Embodiment 3 except for a process for forming the first and second holes 214a and 314a. That is, when the first and second holes 214a and 314a are formed through the first and second semiconductor chips 210 and 310, respectively, the first and second holes 214a and 314a are provided with the lower width greater than the upper width. Herein, any further illustrations with respect to the same processes are omitted for brevity.

According to the present invention, substantially the same or different semiconductor chins are three-dimensionally stacked in the single package. Further, the conductive pad and the conductive bump are bonded to each other to electrically connect the stacked semiconductor chips together. Thus, the process for protruding the conductive pad may be carried out by the above-mentioned single process without performing several complicated processes. As a result, the packages of the present invention may have an improved mass productivity and reliability.

A stacked-type wafer level package in accordance with one aspect of the invention includes a semiconductor chip through which a hole is formed, a conductive pattern and a conductive bump. The conductive pattern includes a conductive trace formed on an upper face of the semiconductor chip and electrically connected to the semiconductor chip, and a conductive pad extending from the conductive trace through the hole. The conductive pad is not protruded from a lower face of the semiconductor chip. The conductive bump is positioned on the conductive trace over the conductive pad.

A wafer-level stack package in accordance with another aspect of the invention includes a first package and a second package stacked on the first package. The first package includes a first semiconductor chip through which a first hole is formed, a first conductive pattern and a first conductive bump. The first conductive pattern includes a first conductive trace formed on an upper face of the first semiconductor chip and electrically connected to the first semiconductor chip, and a first conductive pad extending from the first conductive trace through the first hole. The first conductive pad is not protruded from a lower face of the first semiconductor chip. The first conductive bump is positioned on the first conductive trace over the first conductive pad. The second package includes a second semiconductor chip through which a second hole is formed, a second conductive pattern and a second conductive bump. The second semiconductor chip is placed over the first semiconductor chip. The second conductive pattern includes a second conductive trace formed on an upper face of the second semiconductor chip and electrically connected to the second semiconductor chip, and a second conductive pad extending from the second conductive trace through the second hole. The second conductive pad is not protruded from a lower face of the second semiconductor chip. Further, the second pad is electrically connected to the first conductive bump of the first package. The second conductive bump is positioned on the second conductive trace over the second conductive pad.

In a method of manufacturing a stacked-type wafer level package in accordance with still another aspect of the invention, a hole is formed from an upper face of a semiconductor chip. Here, the hole is not exposed through a lower face of the semiconductor chip. A conductive pattern is formed on the upper face of the semiconductor chip and in the hole. Here, the conductive pattern includes a conductive trace that is formed on an upper face of the semiconductor chip and electrically connected to the semiconductor chip, and a conductive pad that fills up the hole. A conductive bump is formed on the conductive trace over the conductive pad. The lower face of the semiconductor chip is partially removed to expose the conductive pad.

In a method of manufacturing a wafer-level stack package in accordance with another aspect of the invention, a first package is prepared. Here, the first package includes a first semiconductor chip through which a first hole is formed, a first conductive pattern and a first conductive bump. The first conductive pattern includes a first conductive trace formed on an upper face of the first semiconductor chip and electrically connected to the first semiconductor chip, and a first conductive pad extending from the first conductive trace through the first hole. The first conductive pad is not protruded from a lower face of the first semiconductor chip. The first conductive bump is positioned on the first conductive trace over the first conductive pad. A second package is prepared. Here, the second package includes a second semiconductor chip through which a second hole is formed, a second conductive pattern and a second conductive bump. The second conductive pattern includes a second conductive trace formed on an upper face of the second semiconductor chip and electrically connected to the second semiconductor chip, and a second conductive pad extending from the second conductive trace through the second hole. The second conductive pad is not protruded from a lower face of the second semiconductor chip. The second conductive bump is positioned on the second conductive trace over the second conductive pad. The second package is then stacked on the first package to electrically connect the second conductive pad to the first conductive bump.

Having described the preferred embodiments of the present invention, it is noted that modifications and variations can be made by persons skilled in the art in light of the above teachings. It is therefore to be understood that changes may be made in the particular embodiments of the present invention disclosed which are within the scope and the spirit of the invention outlined by the appended claims.

What is claimed is:

1. A stacked-type wafer level package comprising:
a semiconductor chip having a hole;
a conductive pattern including a conductive trace and a conductive pad, the conductive trace arranged on an upper face of the semiconductor chip and electrically connected to the semiconductor chip, and the conductive pad extending from the conductive trace through the hole and not protruded from a lower face of the semiconductor chip; and
a conductive bump arranged on the conductive trace over the conductive pad.

2. The stacked-type wafer level package of claim 1, wherein the hole has an upper width and lower width, wherein the lower width is larger than the upper width.

3. The stacked-type wafer level package of claim 2, wherein the hole has a tapered shape.

4. The stacked-type wafer level package of claim 1, wherein the conductive pad has a lower end that is substantially level with the lower face of the semiconductor chip.

5. The stacked-type wafer level package of claim 1, wherein the conductive pad comprises copper, gold or tungsten.

6. The stacked-type wafer level package of claim 1, wherein the conductive bump has a flat upper face.

7. The stacked-type wafer level package of claim 1, further comprising a first insulation layer that is interposed between the upper face of the semiconductor chip and the conductive trace, and between an inner wall of the hole and the conductive pad.

8. The stacked-type wafer level package of claim 7, further comprising a seed layer interposed between the first insulation layer and the conductive pad.

9. The stacked-type wafer level package of claim 8, further comprising a barrier layer interposed between the first insulation layer and the seed layer.

10. The stacked-type wafer level package of claim 9, wherein the barrier layer comprises a titanium layer, a titanium nitride layer, a titanium tungsten layer, a platinum silicon layer, an aluminum layer or an alloy layer.

11. The stacked-type wafer level package of claim 1, further comprising a second insulation layer arranged on the semiconductor chip and the conductive trace, and having an opening for exposing the conductive bump.

12. The stacked-type wafer level package of claim 1, wherein the conductive bump has a substantially spherical upper face.

13. A wafer-level stack package comprising:
a first package including:
a first semiconductor chip that has a first hole;
a first conductive pattern that includes a first conductive trace arranged on an upper face of the first semiconductor chip and electrically connected to the first semiconductor chip and a first conductive pad extending from the first conductive trace through the first hole; and
a first conductive bump arranged on the first conductive trace over the first conductive pad; and
a second package including:
a second semiconductor chip that has a second hole; and
a second conductive pattern that includes a second conductive trace arranged on an upper face of the second semiconductor chip and electrically connected to the second semiconductor chip and a second conductive pad extending from the second conductive trace through the second hole and electrically connected to the first conductive bump of the first package and not protruded from a lower face of the second semiconductor chip, and a second conductive bump formed on the second conductive trace over the second conductive pad.

14. The wafer-level stack package of claim 13, wherein the first and second holes have an upper width and a lower width, wherein the lower width is larger than the upper width.

15. The wafer-level stack package of claim 13, wherein the second package further includes a second conductive bump arranged on the second conductive trace over the second conductive pad.

16. A method of manufacturing a stacked-type wafer level package, comprising:
forming a preliminary hole from an upper face of a semiconductor chip;
forming a conductive pattern that includes a conductive pad in the preliminary hole and a conductive trace on the upper face of the semiconductor chip, the conductive pattern electrically connected to the semiconductor chip;
forming a conductive bump on the conductive trace over the conductive pad; and
partially removing the lower face of the semiconductor chip thereby exposing the conductive pad.

17. The method of claim 16, wherein the preliminary hole has an upper width and lower width, wherein the lower width is larger than the upper width.

18. The method of claim 17, wherein the preliminary hole has a tapered shape.

19. The method of claim 16, wherein the lower face of the semiconductor chip is removed by a wet etching process.

20. The method of claim 16, wherein forming the conductive pattern comprises:
forming a first insulation layer on the upper face of the semiconductor chip and an inner wall of the preliminary hole;
forming a seed layer on the first insulation layer;
performing a plating process on the seed layer to form the conductive pad in the preliminary hole and a conductive layer on the upper face of the semiconductor chip; and
patterning the conductive layer to form the conductive trace.

21. The method of claim 20, further comprising forming a barrier layer between the first insulation layer and the seed layer.

22. The method of claim 16, wherein forming the conductive bump comprises:
forming a photoresist pattern on the semiconductor chip and the conductive trace, the photoresist pattern exposing an upper face of the conductive trace over the conductive pad;
performing a plating process on the upper face of the conductive trace exposed through the photoresist pattern to form the conductive bump on the upper face of the conductive trace; and
removing the photoresist pattern.

23. The method of claim 16, further comprising forming a second insulation layer on the semiconductor chip and the conductive trace, the second insulation layer having an opening exposing the conductive bump.

24. A method of manufacturing a stacked-type wafer level package, comprising:
forming a preliminary hole from an upper face of a semiconductor chip, the preliminary hole not exposed through a lower face of the semiconductor chip;
forming a first insulation layer on the upper face of the semiconductor chip and an inner wall of the preliminary hole;
forming a seed layer on the first insulation layer;
performing a plating process on the seed layer to form a conductive pad in the preliminary hole and a conductive layer on the upper face of the semiconductor chip;
patterning the conductive layer to form a conductive trace;
forming a photoresist pattern on the semiconductor chip and the conductive trace, the photoresist pattern exposing an upper face of the conductive trace over the conductive pad;
forming a conductive bump on the upper face of the conductive trace exposed through the photoresist pattern;
removing the photoresist pattern;
partially removing the lower face of the semiconductor chip, the first insulation layer, the barrier layer, the seed layer and the conductive pad to form a hole exposing the conductive pad; and
forming a second insulation layer on the semiconductor chip and the conductive trace, the second insulation layer having an opening exposing the conductive bump.

25. A method of manufacturing a wafer-level stack package, comprising:
forming a first package that includes:
a first semiconductor chip having a first hole;
a first conductive pattern including a first conductive trace that is formed on an upper face of the first semiconductor chip and electrically connected to the first semiconductor chip and a first conductive pad that extends from the first conductive trace through the first hole, wherein the first conductive pad does not extend below a lower face of the first semiconductor chip; and
a first conductive bump formed on the first conductive trace over the first conductive pad;
forming a second package that includes:
a second semiconductor chip having a second hole;
a second conductive pattern including a second conductive trace that is formed on an upper face of the second semiconductor chip and electrically connected to the second semiconductor chip and a second conductive pad that extends from the second conductive trace through the second hole; and
a second conductive bump formed on the second conductive trace over the second conductive pad; and
stacking the second package on the first package to electrically connect the second conductive pad of the second package to the first conductive bump of the first package.
